(19) United States
(12) Patent Application Publication
(10) Pub. No.: US 2013/0201633 A1
(43) Pub. Date: Aug. 8, 2013

(54) STRUCTURE OF SURVEILLANCE DEVICE

(71) Applicant: MIN-CHIEH HSU, New Taipei City (TW)

(72) Inventor: MIN-CHIEH HSU, New Taipei City (TW)

(21) Appl. No.: 13/367,319

(22) Filed: Feb. 6, 2012

(51) Int. Cl. H05K 7/00

(52) U.S. Cl. 361/748; 361/679.01

(57) ABSTRACT

The present invention relates to a surveillance device, which includes a device body, a display module mounted to at least one side surface of the device body, and at least one light-emitting diode mounted to at least one side of the device body. The display module can be a liquid crystal display (LCD) or an LED display screen. With the above arrangement, the operation of light-emitting diode helps identifying the location where the device body is mounted and also helps identifying if the device body is in normal operation and further, the arrangement of the display module provides practical advantages of criminal deterrence, advertisement effect, status notification, and information transmission.

### TECHNICAL FIELD OF THE INVENTION

The present invention generally relates to a surveillance device, and more particularly to an improved structure of surveillance device for criminal deterrence, information transmission, and position identification.

### DESCRIPTION OF THE PRIOR ART

Public security issue becomes more and more serious for the modem society so that electronic surveillance devices are commonly installed in most of the public places, resident buildings, or even private houses for personnel control in order to prevent unauthorized access that might lead to criminal activities, such as theft, damage, and injury. The use of surveillance devices helps reducing expense of man power and may also makes a record of the process of an event when an accident occurs.

Most of the surveillance devices available in the market are only of the function of recording and contain no means for deterring thefts or criminals.

Further, it is usually impossible to identify from the outside appearance of a surveillance device if the surveillance device is in normal operation and it is also hard to identify, among a number of surveillance devices, which one of the surveillance devices is out of order. It is often the case that a specific surveillance device is found to be out of order when an attempt is made to retrieve image data from the surveillance device subsequently to the occurrence of an event, so that it is impossible to retrieve the desired image data.

Thus, it is desired to provide a technical solution that overcomes the above discussed problems.

### SUMMARY OF THE INVENTION

In view of the above, the present invention aims to provide an improvement of surveillance device that shows the functionalities of criminal deterrence and information transmission.

The primary objective of the present invention is that with an arrangement of light-emitting diodes and display modules, an improved structure of surveillance device that shows the functionalities of illuminating and eye-catching, criminal deterrence, advertisement effect, and information transmission is provided.

To achieve the above objective, the present invention provides a surveillance device, which comprises a device body, at least one display module mounted to at least one side surface of the device body, and at least one light-emitting diode mounted to at least one side of the device body. The display module can be a liquid crystal display (LCD) or an LED display screen. The device body comprises a circuit board in information connection with the display module. The device body is electrically connected to a power supply module.

With the above arrangement, the device body receives electrical power supplied from the power supply module and the operation of the light-emitting diode and the display module clearly identify the location where the device body is mounted and helps identifying if the device body is in normal operation. Further, the practical advantages of notifying an operator of the status and deterring criminals, providing an effect of advertisement, and transmitting information are realized.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view showing a preferred embodiment according to the present invention.

FIG. 2 is a perspective view showing an operation of the preferred embodiment of the present invention.

FIG. 3 is a perspective view showing an operation of the preferred embodiment of the present invention.

FIG. 4 is a perspective view showing an operation of the preferred embodiment of the present invention.

FIG. 5 is a perspective view showing an operation of the preferred embodiment of the present invention.

FIG. 6A is a perspective view showing an operation of another preferred embodiment of the present invention.

FIG. 6B is a perspective view showing an operation of another preferred embodiment of the present invention.

FIG. 7 is a perspective view showing an operation of another preferred embodiment of the present invention.

FIG. 8 is a perspective view showing an operation of another preferred embodiment of the present invention.

FIG. 8A is a perspective view showing an operation of another preferred embodiment of the present invention.

FIG. 9 is a perspective view showing an operation of another preferred embodiment of the present invention.

FIG. 9A is a perspective view showing an operation of another preferred embodiment of the present invention.

FIG. 10 is a perspective view showing an operation of another preferred embodiment of the present invention.

FIG. 10A is a perspective view showing an operation of another preferred embodiment of the present invention.

FIG. 11 is a perspective view showing an operation of another preferred embodiment of the present invention.

FIG. 11A is a perspective view showing an operation of another preferred embodiment of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

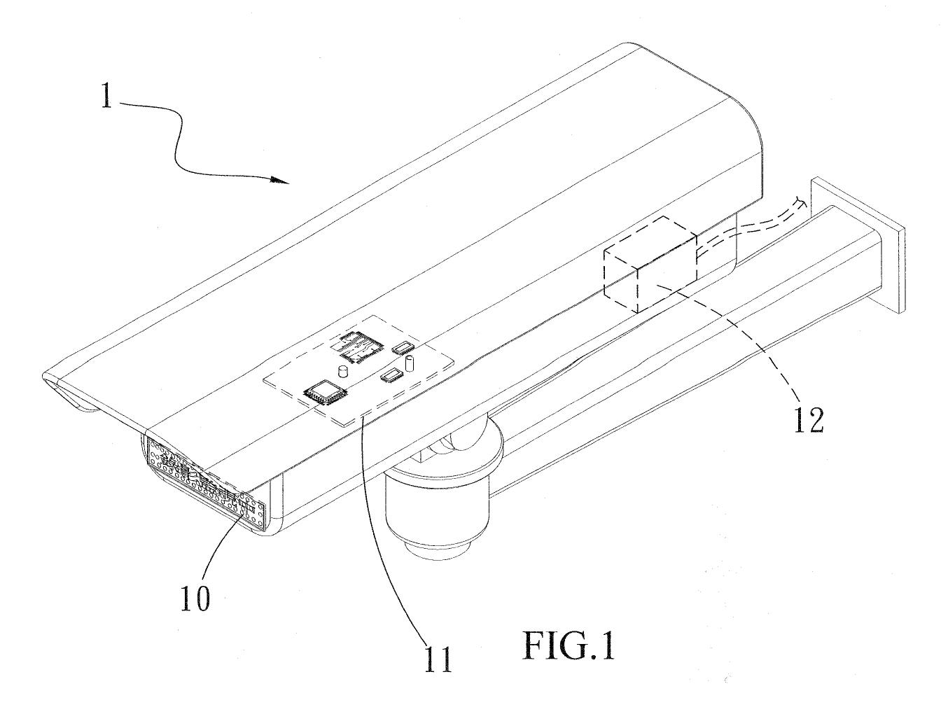

Referring to FIG. 1, which is a perspective view showing a preferred embodiment according to the present invention, the drawing clearly shows that the present invention provides an improved structure of surveillance device, which comprises a device body 1 and a display module 10 mounted to at least one side of the device body 1. The display module 10 can be for example a liquid crystal display (LCD) or a light-emitting diode (LED) display screen. The device body 1 comprises a circuit board 11 in information connection with the display module 10. The device body 1 is electrically connected with a power supply module 12.

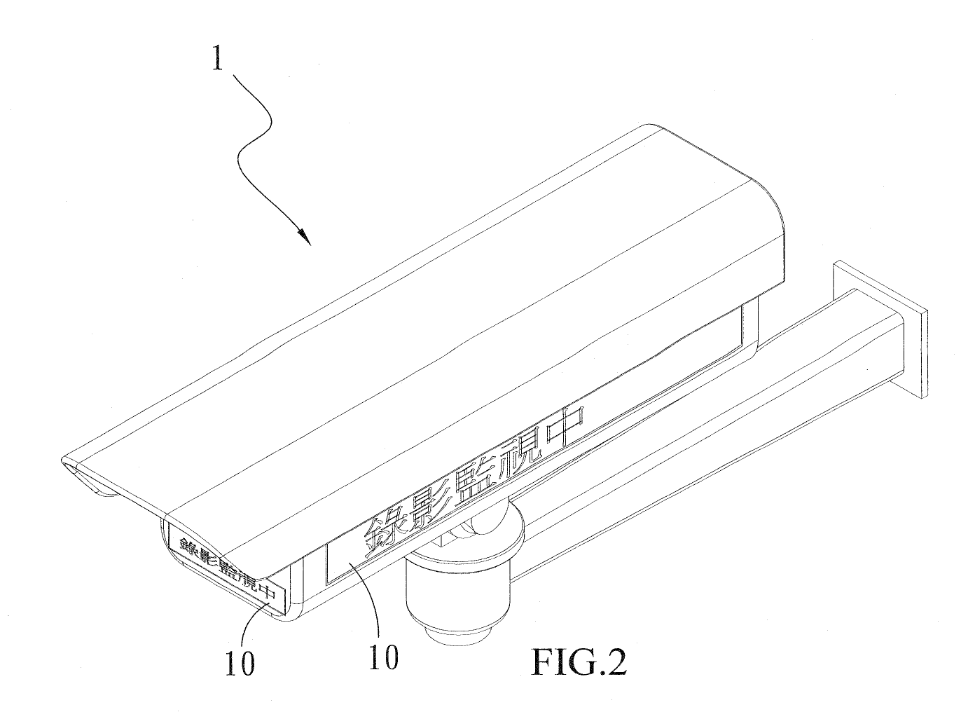

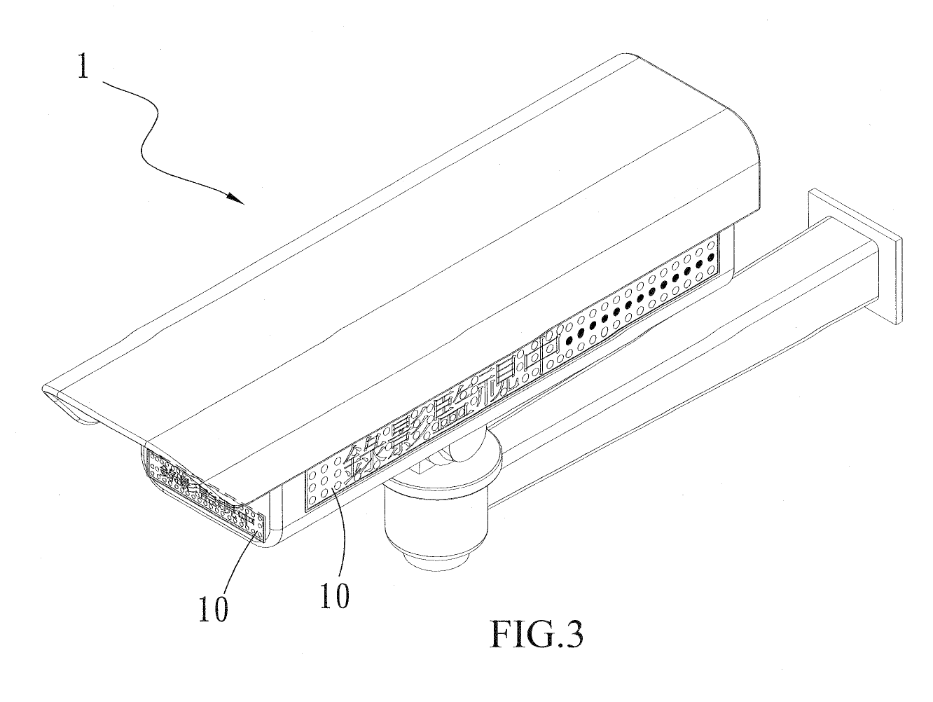

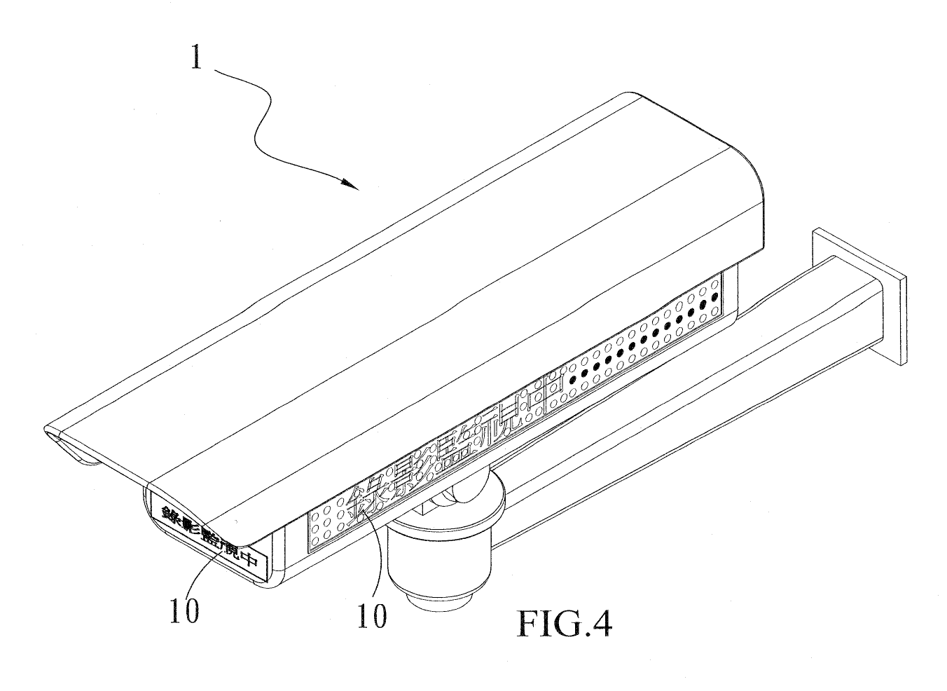

With the above described arrangement, the operation of the present invention is as follows. Reference is now made to FIGS. 2-5, which are perspective views showing the operations of the preferred embodiment of the present invention, these drawings clearly show that an example is illustrated with two side surfaces of the device body 1 are provided with display modules 10. When the device body 1 is mounted in a surveillance space and put into operation, the display modules 10 of the device body 1 display illuminating characters, such as “video recording”, “video taping, please smile”, and “welcome”, in which the display modules 10 can each be either an LCD or an LED display screen. The displaying operation of the display modules 10 can be displaying though LCD (see FIG. 2), displaying through LED display screen (see FIG. 3), or a combined displaying through both LED display screen and LCD (see FIG. 4), so that general people may immediately identify the location of the device body 1 and also deterrence to people attempting to commit a crime can be realized.

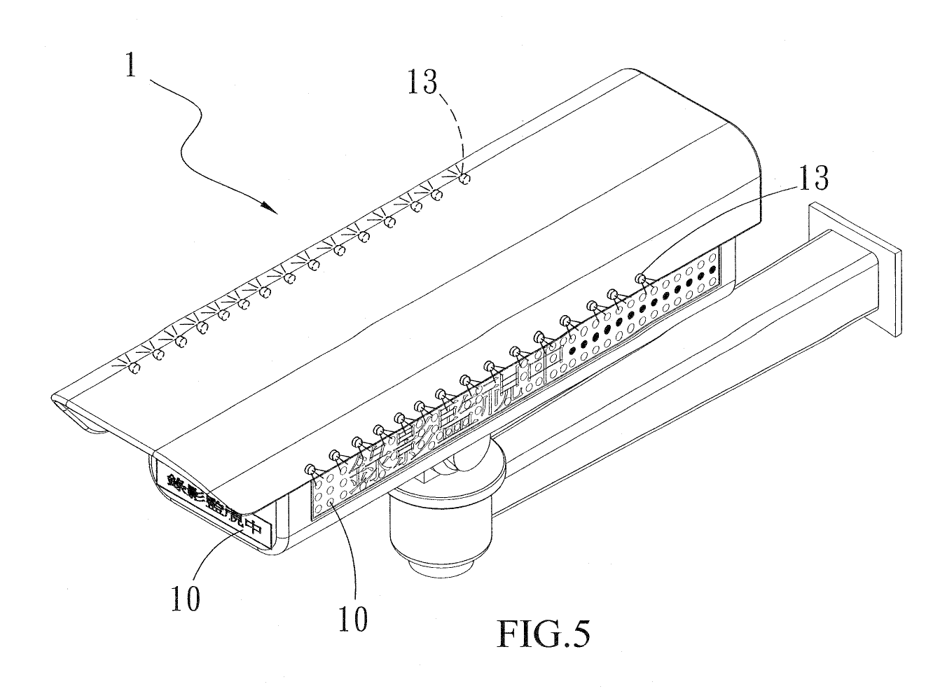

Further, also referring to FIG. 5, the device body 1 as described above, may be provided, on at least one side surface thereof with a plurality of light-emitting diodes 13, which is operative in accordance with the operation of the display module 10, so that it is easy to identify if the device body 1 is out of order to thereby facilitate maintenance operation conducted by a maintenance operator and to provide practical improvements of illuminating and eye-catching, transmission of information, status notification, and advertisement effect.

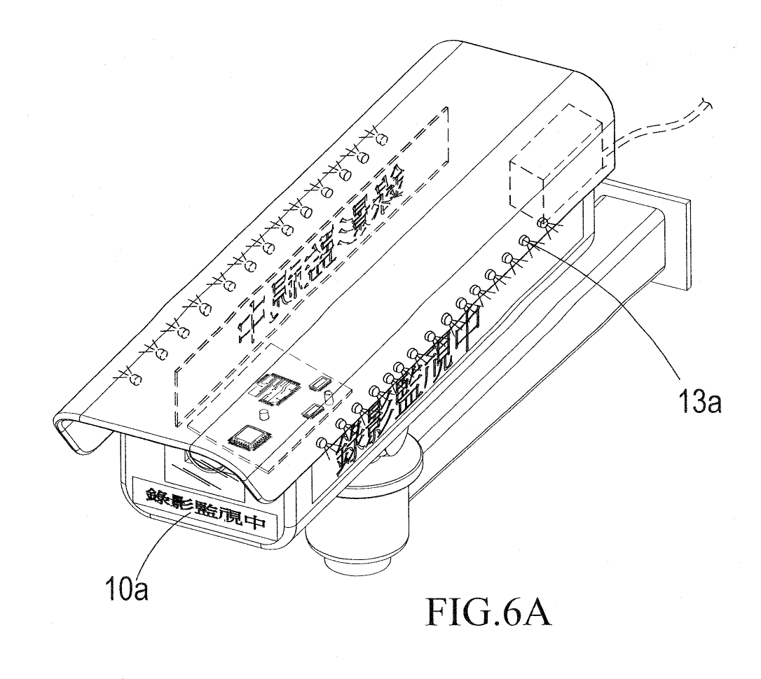

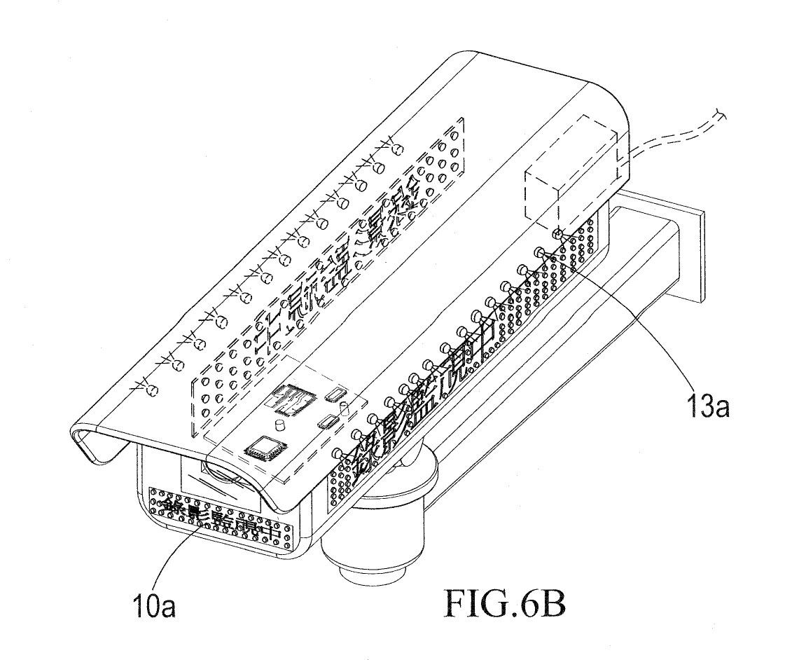

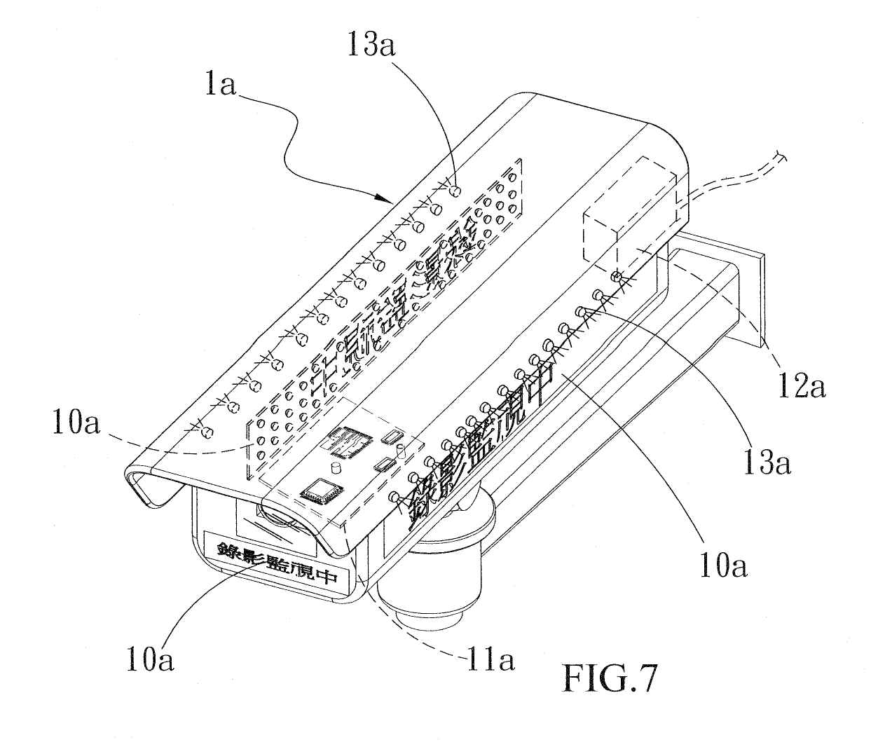

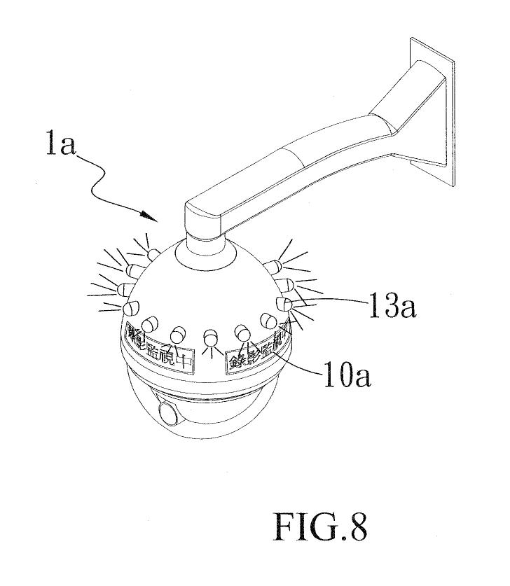

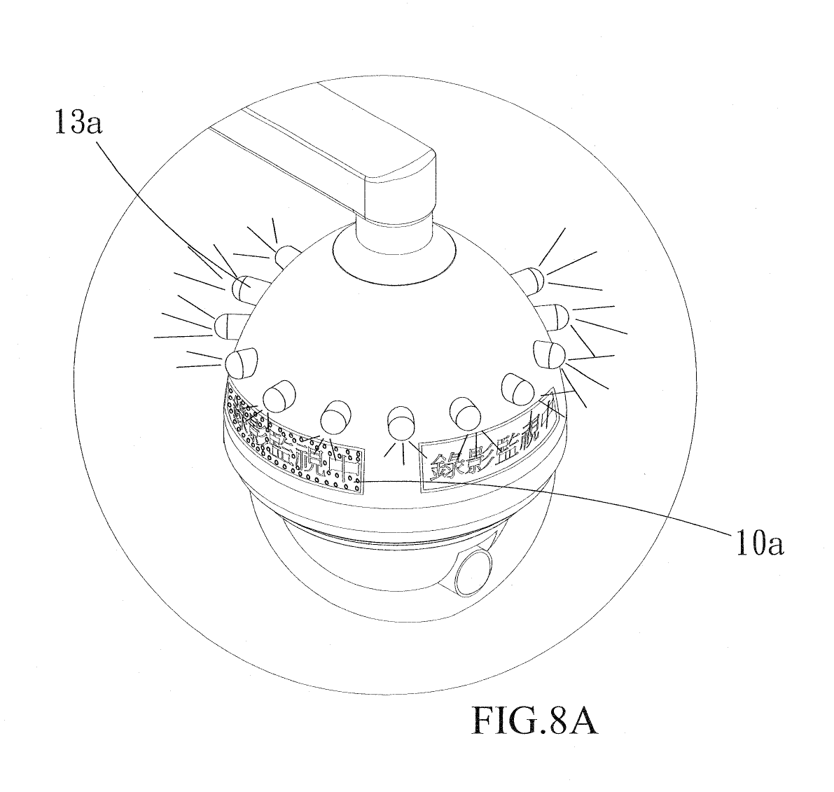

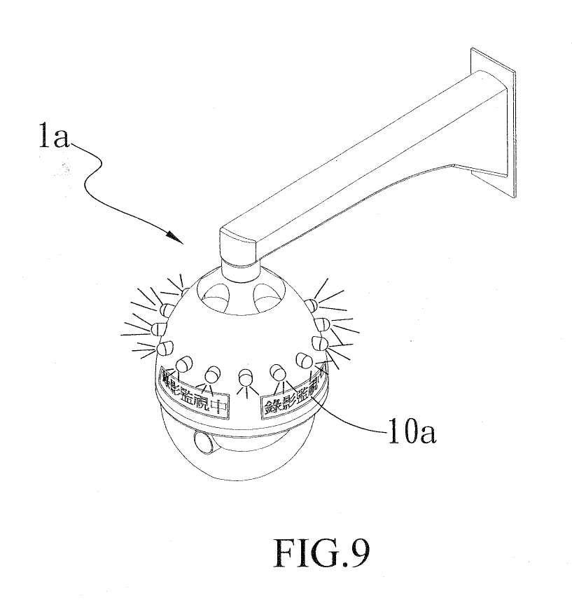

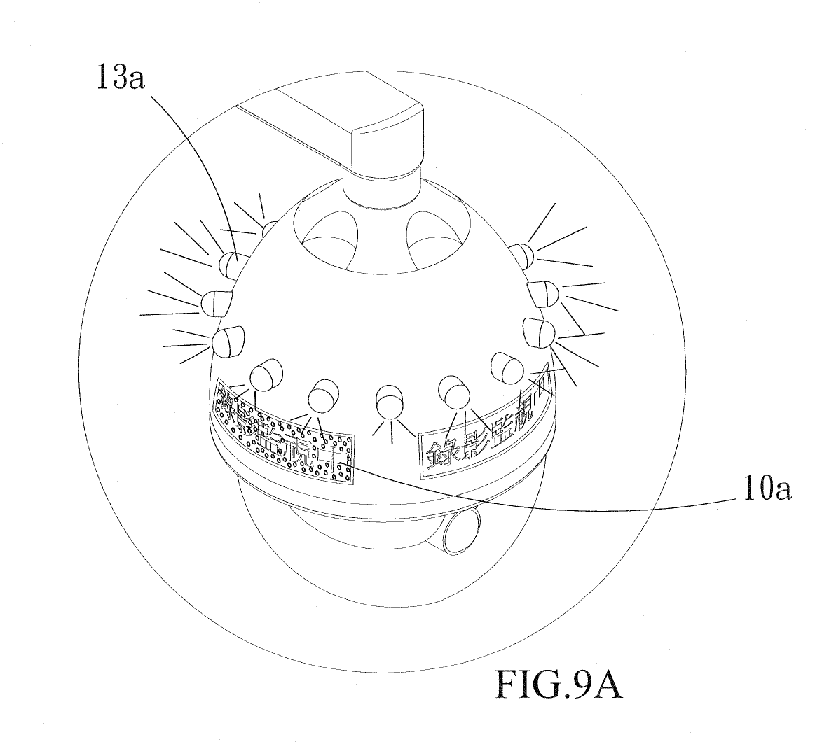

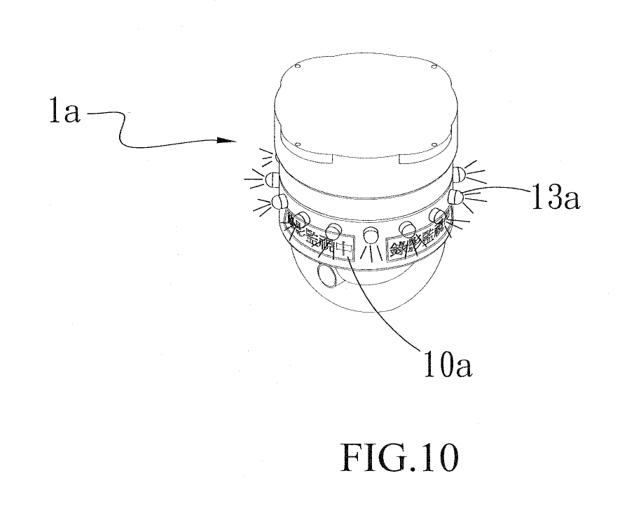

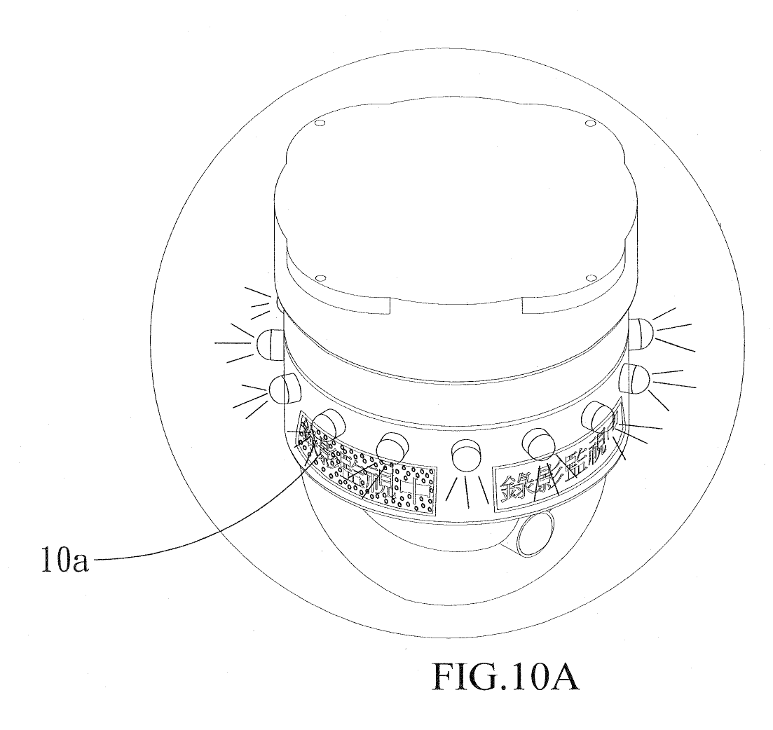

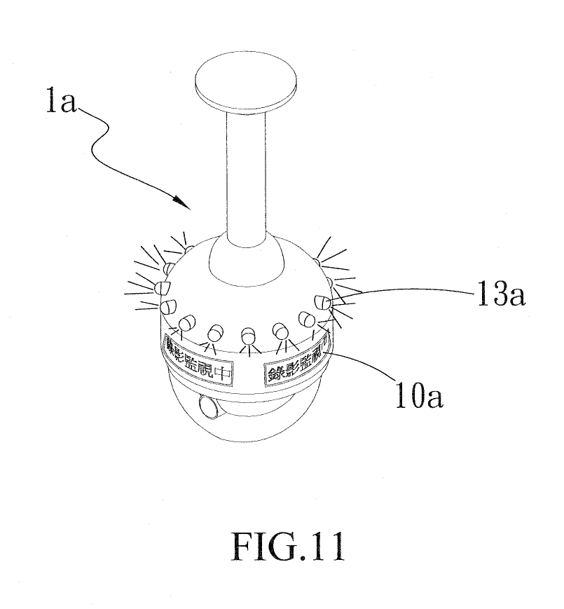

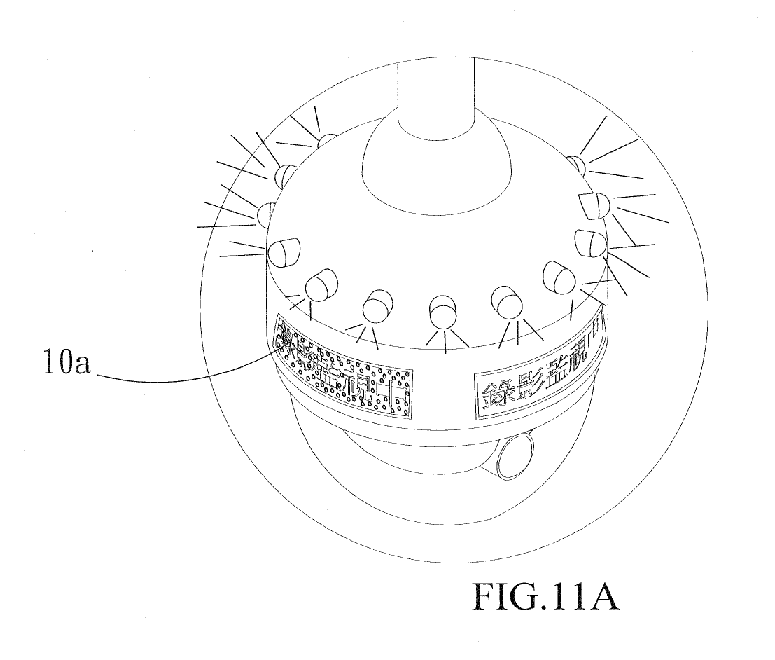

Referring to FIGS. 6A-11A, which are perspective views showing the operations of another preferred embodiment of the present invention, these drawings clearly show that an example that a device body 1a is provided, on three side surfaces thereof, with display modules 10a is illustrated. When the device body 1a is mounted in a surveillance space and is put into operation by being supplied with electrical power from a power supply module 12a, the display modules 10a mounted to the three side surfaces of the device body 1a display illuminating characters, such as “video recording”, “video taping, please smile”, and “welcome”, in which the display modules 10 can each be either an LCD or an LED display screen. The display modules 10a are in information connection with a circuit board 11a. The displaying operation of the display modules 10a can be displaying though LCD (see FIG. 6A), displaying through LED (see FIG. 6B), or a combined displaying through both LED and LCD (see FIGS. 7-11A), so as to effect deterrence to people attempting to commit a crime. Further, the device body 1a is provided with light-emitting diodes 13a, whereby according to the illumination of the display modules 10a and light-emitting diodes 13a, a maintenance operator may identify if the device body 1a is out of order, so as to facilitate the maintenance operation by the operator. The above described operation clearly shows that the present invention provides practical advantages in respect of illuminating and eye-catching, advertisement effect, status notification, and transmission of information.

However, it is noted that the above description shows only some preferred embodiments of the present invention. The scope of protection that the application is seeking for is not limited to such a description and it is intended to have all simple modifications and equivalent variations of what described and illustrated in the specification and drawings covered in the scope of protection of the present invention.

Referring to all the drawings, the present invention, when put into use, shows the following advantages as compared to the prior art:

The arrangement of display modules 10 and light-emitting diodes 13 on the device body 1 may effect the practical advantages of illuminating and eye-catching status notification, information transmission, facilitating maintenance, and advertisement effect.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A surveillance device, comprising:
a device body; and
a display module mounted to a side surface of the device body.

2. The surveillance according to claim 1, wherein the display module comprises a liquid crystal display (LCD) or an LED display screen.

3. The surveillance according to claim 1, wherein the device body comprises a circuit board in information connection with the display module.

4. The surveillance according to claim 1, wherein the device body is electrically connected to a power supply module.

5. A surveillance device, comprising:
a device body;
a display module mounted to at least a side surface of the device body; and
at least one light-emitting diode mounted to at least one side of the device body.

6. The surveillance according to claim 5, wherein the display module comprises a liquid crystal display (LCD) or an LED display screen.

7. The surveillance according to claim 5, wherein the device body comprises a circuit board in information connection with the display module.

8. The surveillance according to claim 5, wherein the device body is electrically connected to a power supply module.
